(19) United States
(12) Patent Application Publication
(10) Pub. No.: US 2015/0371971 A1
(43) Pub. Date: Dec. 24, 2015

(54) SEMICONDUCTOR DEVICE

(71) Applicant: Panasonic Corporation, Osaka (JP)

(72) Inventors: KENJI YOKOYAMA, Kyoto (JP); TAKESHI KAWABATA, Osaka (JP); TAKASHI YUI, Shiga (JP)

(21) Appl. No.: 14/841,768

(22) Filed: Sep. 1, 2015

Related U.S. Application Data
(63) Continuation of application No. PCT/JP2013/006013, filed on Oct. 9, 2013.

(30) Foreign Application Priority Data
Mar. 8, 2013 (JP) 2013-046487

(51) Int. Cl. H01L 25/065; H01L 23/498; H01L 25/18; H01L 23/31; H01L 23/00

(52) U.S. Cl. CPC H01L 25/0657; H01L 23/3128; H01L 24/06; H01L 24/16; H01L 24/49; H01L 25/18; H01L 23/49827; H01L 2224/0401; H01L 2224/04042; H01L 2224/04105; H01L 2224/05548; H01L 2224/06181; H01L 2224/16146; H01L 2224/73204; H01L 2224/73207; H01L 2225/0651; H01L 2225/06513; H01L 2225/06517; H01L 2225/06541; H01L 2924/1434; H01L 2924/15311

(57) ABSTRACT

To provide a CoC type semiconductor device capable of preventing a power supply voltage from dropping (IR drop) in a center portion of a chip, and preventing deterioration in timing reliability. The semiconductor device includes a substrate, a first semiconductor chip placed on the substrate, having a circuit formation surface on an upper surface provided opposite to a surface facing the substrate, and including a TSV electrode and a connection pad electrically connected to the substrate, a second semiconductor chip placed on the upper surface of the first semiconductor chip, and electrically connected to the first semiconductor chip through a bump, a connection member for electrically connecting the connection pad of the first semiconductor chip to the substrate, and a redistribution layer formed on the upper surface of the first semiconductor chip, and electrically connected to the TSV electrode.

### BACKGROUND OF THE INVENTION

1. Field of the Invention

The present disclosure relates to a semiconductor device, and particularly to a semiconductor device having a chip on chip (CoC) structure.

2. Description of the Related Art

In recent years, as semiconductors have been increasingly miniaturized, a number of transistors constituting an LSI goes on increasing. Furthermore, as a component of the LSI, especially a system becomes complicated and large, memory capacity needed by a system LSI is problematically increased, so that there is a need for a method for highly efficiently mounting the system LSI having a large-scale memory.

Meanwhile, as for a method for connecting the LSI to a package, a wire bonding method and a flip chip method are widely used. When a memory is mounted by the mounting methods, the memory is to be mounted on a system LSI chip, a chip mounting substrate, or a mounting substrate, so that mounting capacity is limited, a large substrate mounting area is needed, and mounting cost is high. To solve these problems, the CoC structure is employed.

A semiconductor device having a general CoC structure is provided such that semiconductor chips each having a plurality of pads on its circuit formation surface are disposed so that their circuit formation surfaces are opposed to each other, and the semiconductor chips are electrically connected to each other through bumps disposed on the pads. When such a CoC structure is employed, the plurality of semiconductor chips can be mounted on the substrate, so that the chips can be efficiently connected in a small area, compared with the normal wire bonding and flip chip methods.

Meanwhile, when the CoC structure is employed, a power supply voltage is supplied to an upper semiconductor chip through a lower semiconductor chip, so that the problem is that voltage drop (IR drop) occurs due to lack of power supply voltage in the upper semiconductor chip. In addition, since the lower semiconductor chip is covered with the upper semiconductor chip, it is difficult to supply the power supply voltage from a part just above a center portion of the lower semiconductor chip, so that voltage drop also occurs in supplying the power supply voltage to the center portion of the lower semiconductor chip. Thus, an operation speed of a transistor of the LSI becomes uneven due to this influence, so that this influence is to be considered, otherwise operation timing of the LSI is affected, and serious problems are caused with LSI operation failure and an yield.

To solve the above problems, PTL 1 discloses a semiconductor device in which the CoC structure is employed, and mounting positions of a plurality of semiconductor chips stacked on the wiring substrate are displaced so that a power supply voltage can be directly supplied from the substrate to the upper mounted chip.

Furthermore, PTL 2 discloses a semiconductor device in which the CoC structure is employed, and a semiconductor logic circuit chip which is smaller than a semiconductor memory chip is stacked on the semiconductor memory chip, in order to miniaturize the semiconductor device.

Furthermore, PTL 3 discloses a semiconductor device in which interposer substrates are provided between a plurality of semiconductor elements. More specifically, a pad is formed on one surface of the interposer substrate, and a pad is formed on the other surface of the interposer substrate so as to be disposed at a plane position matching a plane position of a pad of the semiconductor element positioned on the other surface, and the pad formed on the one surface is connected to the pad formed on the other surface in the interposer substrate.

### CITATION LIST

### Patent Literatures

PTL1: Unexamined Japanese Patent Publication No. 2008-159607

PTL2: Unexamined Japanese Patent Publication No. 2010-141080

PTL3: Unexamined Japanese Patent Publication No. 2010-278334

According to the semiconductor device in PTL 1, since it is assumed that the stacked positions of the chip mounted on the upper side and the chip mounted on the lower side are displaced, the power supply voltage only can be directly supplied from the substrate to the one side of the chip surface facing the substrate, so that it is extremely difficult to stably supply the power supply voltage in a chip surface. In addition, since the chip is displaced, an area of a resin mounting substrate is increased, and cost is increased due to the increase in size of the substrate.

According to the semiconductor device in PTL 2, since it is assumed that the chip mounted on the upper side is smaller than the chip mounted on the lower side, the CoC structure cannot be employed in a case where the lower side chip is small.

According to the semiconductor device in PTL 3, the semiconductor chips vertically stacked through a through-silicon via (TSV) are connected through the interposer substrate, circuits on the upper and lower chips can be efficiently connected, but regarding the prevention in power supply voltage drop in the chip center portion, its effect is limited.

### SUMMARY OF THE INVENTION

According to the present disclosure, in a semiconductor device including a plurality of semiconductor chips connected as a CoC structure, provided is a configuration capable of stably supplying a power supply voltage to a center portion of the upper and lower chips at the time of CoC mounting.

According to one aspect of the present disclosure, a semiconductor device includes a substrate, a first semiconductor chip placed on the substrate, having a circuit formation surface on an upper surface provided opposite to a surface facing the substrate, and including a TSV electrode and a connection pad electrically connected to the substrate, a second semiconductor chip placed on the upper surface of the first semiconductor chip, and electrically connected to the first semiconductor chip through a bump, a connection member for electrically connecting the connection pad of the first semiconductor chip to the substrate, and a redistribution layer (RDL) formed on the upper surface of the first semiconductor chip, and electrically connected to the TSV electrode.

According to the aspect, power can be supplied from the substrate to the upper surface of the first semiconductor chip, that is, the circuit formation surface through the TSV electrode formed in the first semiconductor chip, and the redistribution layer formed on the upper surface of the first semiconductor chip. Therefore, the power supply voltage can be stably supplied to the chip center portion.

According to the present disclosure, in the semiconductor device having the plurality of semiconductor chips connected with the CoC form, while the cost is kept down, the power supply voltage can be stably supplied to the center portions of the upper and lower chips at the time of the CoC mounting, without regard to the sizes of the upper and lower chips. Therefore, it is possible to prevent timing performance degradation and a functional defect caused by variation in speed of the transistor operation, so that the semiconductor device can be improved in performance and reliability.

### BRIEF DESCRIPTION OF THE DRAWINGS

FIG. 1A is a cross-sectional view schematically showing a configuration of a semiconductor device according to a first exemplary embodiment;

FIG. 1B is a plan view schematically showing a configuration of the semiconductor device according to the first exemplary embodiment;

FIG. 2A is a cross-sectional view schematically showing a configuration of a semiconductor device according to Variation 1 of the first exemplary embodiment;

FIG. 2B is a plan view schematically showing a configuration of the semiconductor device according to Variation 1 of the first exemplary embodiment;

FIG. 3 is a cross-sectional view schematically showing a configuration of a semiconductor device according to Variation 2 of the first exemplary embodiment;

FIG. 4 is a cross-sectional view schematically showing a configuration of the semiconductor device according to Variation 3 of the first exemplary embodiment;

FIG. 5 is a cross-sectional view schematically showing a configuration of a semiconductor device according to Variation 4 of the first exemplary embodiment; and

FIG. 6 is a cross-sectional view schematically showing a configuration of a semiconductor device according to Variation 5 of the first exemplary embodiment.

### DETAILED DESCRIPTION OF THE PREFERRED EMBODIMENT

A semiconductor device according to this exemplary embodiment will be described with reference to the drawings. A common component is marked with the same reference and its description will occasionally not be given.

### First Exemplary Embodiment

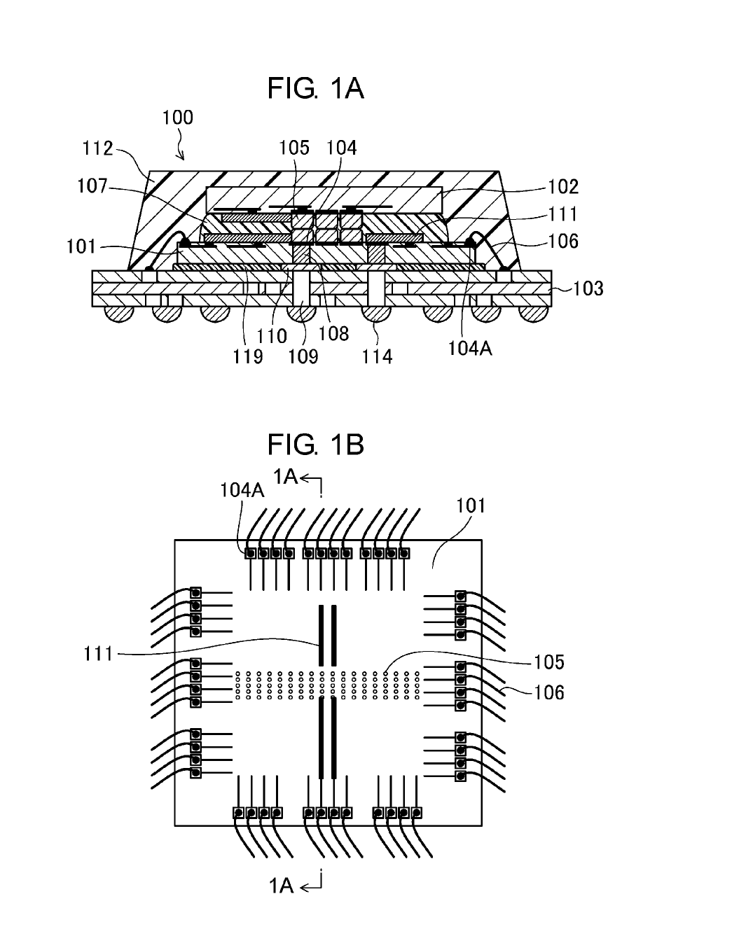

FIGS. 1A and 1B are a cross-sectional view and a plan view, respectively each schematically showing a configuration of a semiconductor device according to this exemplary embodiment. FIG. 1A is the cross-sectional view taken along a line 1A-1A in FIG. 1B.

As shown in FIG. 1A, semiconductor device 100 includes first semiconductor chip 101 formed on a lower side of a stacked structure, second semiconductor chip 102 formed on an upper side of the stacked structure, substrate 103 such as a wiring substrate on which first and second semiconductor chips 101 and 102 are mounted. That is, the chip stacked structure having first and second semiconductor chips 101 and 102 is formed on substrate 103. First semiconductor chip 101 has a circuit formation surface on its upper surface which is opposite to a surface facing substrate 103, and second semiconductor chip 102 has a circuit formation surface on its lower surface which faces the substrate. A plurality of connection terminals 104 are disposed on each of the circuit formation surfaces of first and second semiconductor chips 101 and 102. First semiconductor chip 101 and second semiconductor chip 102 are electrically connected to each other through a plurality of bumps 105 disposed on connection terminals 104. In addition, underfill resin 107 is filled between first semiconductor chip 101 and second semiconductor chip 102. Each of first and second semiconductor chips 101 and 102 serves as, for example, a memory chip or a system chip (system LSI).

Wire bonding pads 104A are formed on first semiconductor chip 101 around a mount region of second semiconductor chip 102. Wire 106 electrically connects wire bonding pad 104A to substrate 103 by wire bonding. Furthermore, through-silicon via (TSV) electrode (silicon penetration electrode) 108 is formed in first semiconductor chip 101. At least one TSV electrode 108 is electrically connected to substrate 103. Here, as one example, at a lower surface of first semiconductor chip 101, TSV electrode 108 is connected to substrate electrode 109 of substrate 103 through a conductive resin or conductive film 110. In addition, TSV electrode 108 in first semiconductor chip 101 may be electrically connected to substrate electrode 109 through solder, a bump, or a redistribution layer, instead of the conductive resin or conductive film 110.

One TSV electrode 108 is disposed at a position matching a position of upper bump 105 when planarly viewed, and electrically connected to upper bump 105. Another TSV electrode 108 is not disposed at the position matching the position of upper bump 105 when planarly viewed, and not electrically connected to upper bump 105. In addition, TSV electrode 108 may be electrically connected or not connected to a wiring in first semiconductor chip 101.

Furthermore, redistribution layer 111 is formed on the upper surface of first semiconductor chip 101. TSV electrode 108 is electrically connected to redistribution layer 111 on the upper surface of first semiconductor chip 101 through a chip surface wiring, for example. A power supply wiring or a ground wiring is connected to redistribution layer 111 in first semiconductor chip 101. Mold resin 112 seals first and second semiconductor chips 101 and 102, and wire 106.

As shown in FIG. 1B, redistribution layer 111 is formed as the power supply (or ground) wiring in a center region of the circuit formation surface of first semiconductor chip 101. Redistribution layer 111 is connected to a lower surface of first semiconductor chip 101 through the connection terminal and TSV electrode 108. In addition, bump 105 for connecting first semiconductor chip 101 to second semiconductor chip 102 may be connected or not be connected to redistribution layer 111.

A plurality of power supply systems can be formed by forming TSV electrode 108 and bump 105 with respect to each of the plurality of power supply systems, and connecting bump 105 to redistribution layer 111 and to an electrode in the chip on first and second semiconductor chips 101 and 102.

Redistribution layer 111 can be formed in the same step as a step of manufacturing bump 105. For example, they are formed by opening a resist in the regions for redistribution layer 111 and bump 105 on first semiconductor chip 101, performing electrolytic plating with Cu and Sn, and removing the resist. A material of redistribution layer 111 and bump 105 may be any material as long as it is a metal material, and a low-resistance metal such as Cu, solder, Ni, Au, Al, or their alloy is more favorably used.

In a case where the power supply and the ground wiring are used in combination, two redistribution layers 111 are drawn to the chip center portion, thereby creating the power supply wirings having two potentials. In this configuration, with redistribution layers 111 drawn to the center portions of first and second semiconductor chips 101 and 102, the power supply voltage can be stably supplied to the chip center portion, so that the power supply voltage can be prevented from dropping in the chip center portion in the CoC structure.

In addition, TSV electrode 108 in first semiconductor chip 101 is connected to substrate electrode 109 through the conductive resin or conductive film 110. When this connection position is set in the center portion of semiconductor chip 101, and a center portion of substrate 103, a power supply wiring path from ball terminal 114 of substrate 103 to an internal element in first semiconductor chip 101 can be shorter, and a resistance can be reduced.

More specifically, a height of redistribution layer 111 is about 3 μm, and this is about three times higher than a diffusion wiring layer (having a height of 1 μm) provided in first and second semiconductor chips 101 and 102. Therefore, wiring resistance of a height component can be reduced to about ⅓. In addition, redistribution layer 111 and bump 105 may be formed of the same metal material as the same layer.

With the above configuration, the power supply voltage can be also stably supplied to a mesh power supply and a vertically-penetrating power supply constituted by wirings in first and second semiconductor chips 101 and 102, through redistribution layer 111 and TSV electrode 108. Furthermore, regarding an influence of a transfer of an L component, since TSV electrode 108 serving as the power supply wiring is thicker than conventional wire 106, the influence on first and second semiconductor chips 101 and 102 can be small. Furthermore, a conductive path extending to substrate 103 through thick TSV electrode 108 can be formed in the center portion of first semiconductor chip 101, so that a heat releasing property can be improved in the CoC stacked type chip.

In addition, in a case where the semiconductor chip is large in size, many terminals (such as half a total number of the terminals) are needed for the wire bonding to supply the power supply voltage, but by partially replacing those terminals with the TSV electrode to share the power supply, a number of the terminals can be reduced, and the chip size can be reduced. That is, a number of the chips obtained per wafer can be increased, and a package size can be miniaturized.

According to a general configuration of a conventional CoC package employing a simple TSV technique, a stacked body constituted by a plurality of chips formed of CoC is directly connected to a mother substrate by flip-chip bonding, or a lower surface of a lower chip is connected after its mounting pitch is increased by redistribution technique. In this configuration, in a case where connection portions having the CoC structure concentrate in a center portion especially, it is necessary to narrow a pitch of the TSVs, and make a redistribution layer fine down on the lower surface of the lower chip.

Meanwhile, according to this exemplary embodiment, the circuit formation surface of the lower chip faces upward, and only the terminal for the power supply voltage (or grounding) is drawn to the substrate through the TSV. With this configuration, a number of the TSVs can be reduced, and the TSVs can be formed at rough pitches, so that the semiconductor device can be manufactured with high yield and at low cost. Furthermore, as for remaining signal lines and power voltage supply lines, they are connected to the wire bonding pads through the wiring in the chip or the redistribution layer.

Furthermore, the power supply voltage terminal extracted through the TSV is formed in such a manner that a pattern having the same potential is connected to the same wiring on the substrate according to a number of its kind, and the plurality of TSVs are connected to the one pattern having the same potential on the substrate.

With the above configuration, a number of the wire bonding pads is reduced, wiring designs on the lower chip and the substrate can be easily designed, and a number of layers and a size of the substrate can be reduced.

### Variation 1 of First Exemplary Embodiment

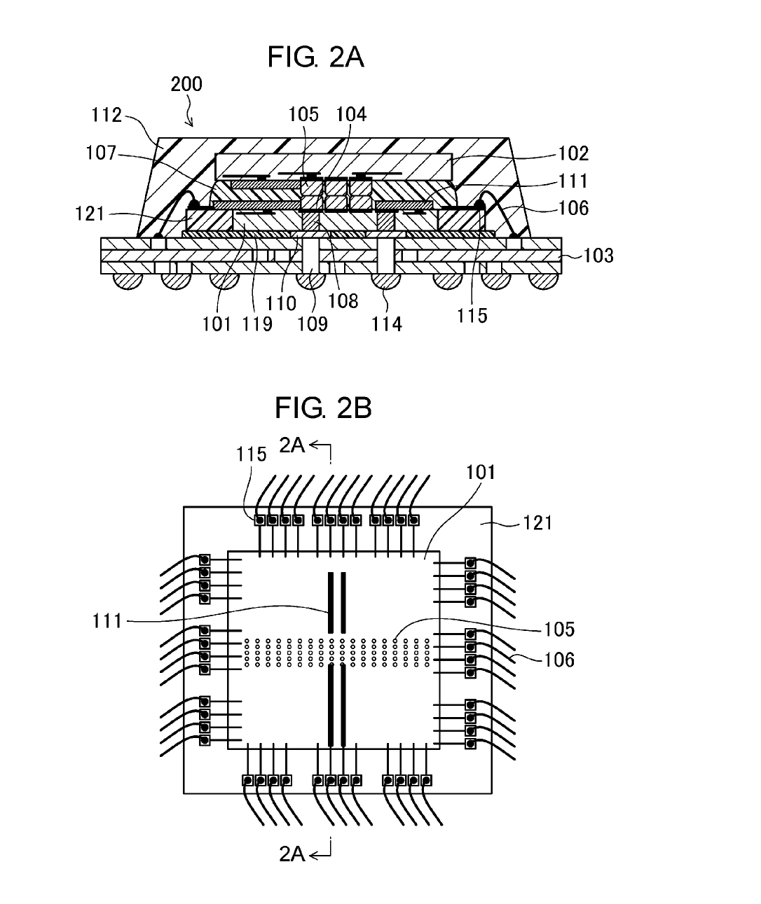

FIGS. 2A and 2B are a cross-sectional view and a plan view, respectively each showing a configuration of semiconductor device 200 according to this variation. FIG. 2A is the cross-sectional view taken along a line 2A-2A in FIG. 2B.

As shown in FIGS. 2A and 2B, according to semiconductor device 200, first semiconductor chip 101 includes expansion portion 121 formed around a chip body when planarly viewed. Expansion portion 121 is made of resin, for example. Thus, wire bonding pad 115 connected to substrate 103 with wire 106 is formed on expansion portion 121.

With this configuration, since expansion portion 121 is formed, the stable chip stacked structure can be realized even when first semiconductor chip 101 is smaller in size than second semiconductor chip 102. Therefore, the power supply voltage can be stably supplied to the chip center portion through redistribution layer 111 serving as the power supply wiring drawn to the chip center portion through TSV electrode 108, so that the power supply voltage can be prevented from dropping in the chip center portion in the CoC structure.

### Variation 2 of First Exemplary Embodiment

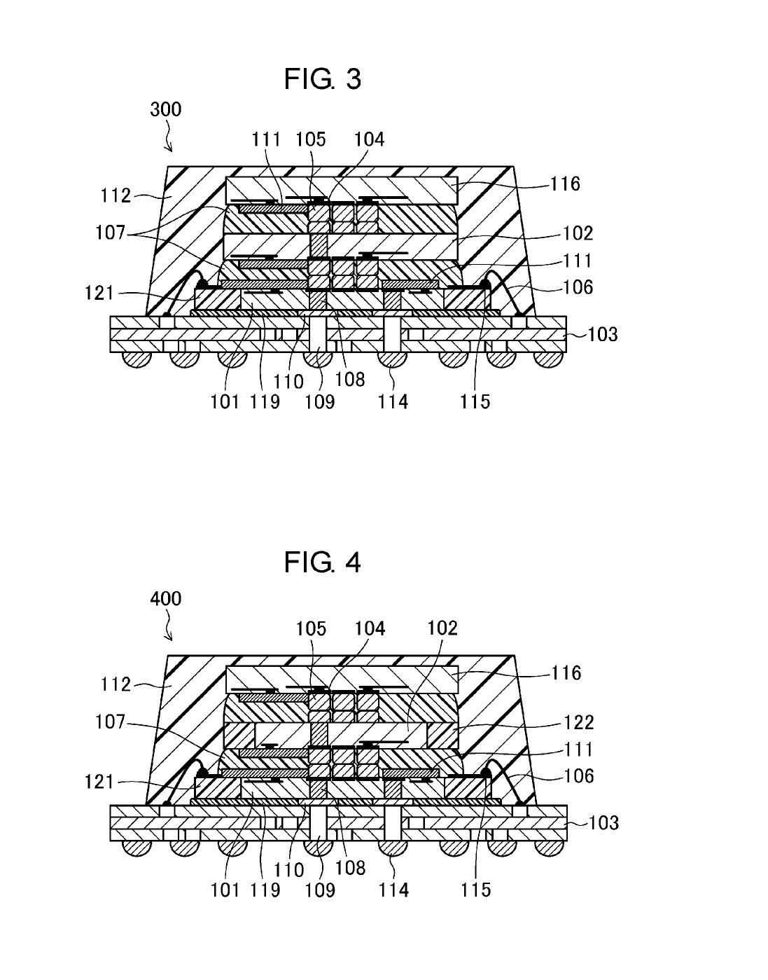

FIG. 3 is a cross-sectional view of semiconductor device 300 according to this variation. As shown in FIG. 3, semiconductor device 300 includes third semiconductor chip 116 placed on an upper surface of second semiconductor chip 102, and electrically connected to second semiconductor chip 102 through at least one bump 105. That is, a chip stacked structure including first, second, and third semiconductor chips 101, 102, and 116 is formed on substrate 103. Third semiconductor chip 116 has a circuit formation surface on its lower surface facing the substrate. A plurality of connection terminals 104 are disposed on the circuit formation surface of third semiconductor chip 116. Second semiconductor chip 102 and third semiconductor chip 116 are electrically connected to each other through a plurality of bumps 105 disposed on connection terminals 104. In addition, underfill resin 107 is filled between second semiconductor chip 102 and third semiconductor chip 116.

At least one TSV electrode 108 is formed in second semiconductor chip 102. TSV electrode 108 in second semiconductor chip 102 is electrically connected to TSV electrode 108 in first semiconductor chip 101 through connection terminal 104 and bump 105. In addition, redistribution layer 111 is formed on the lower surface of third semiconductor chip 116. Redistribution layer 111 of third semiconductor chip 116 is electrically connected to TSV electrode 108 in second semiconductor chip 102 through connection terminal 104 and bump 105.

As described above, when TSV electrode 108 is also formed in second semiconductor chip 102, the power supply voltage can be stably supplied to the chip center portion through redistribution layer 111 serving as the power supply wiring drawn to the chip center portion of third semiconductor chip 116 through TSV electrode 108, so that the power supply voltage can be prevented from dropping in the chip center portion in the CoC structure.

### Variation 3 of First Exemplary Embodiment

FIG. 4 is a cross-sectional view of semiconductor device 400 according to this variation. As shown in FIG. 4, according to semiconductor device 400, second semiconductor chip 102 includes expansion portion 122 formed around a chip body when planarly viewed. Expansion portion 122 is formed of resin, for example.

With this configuration, since expansion portion 122 is formed, a stable chip stacked structure can be realized even when second semiconductor chip 102 is smaller in size than third semiconductor chip 116. Therefore, the power supply voltage can be stably supplied to the chip center portion through redistribution layer 111 serving as the power supply wiring drawn to the chip center portion through TSV electrode 108, so that the power supply voltage can be prevented from dropping in the chip center portion in the CoC structure.

### Variation 4 of First Exemplary Embodiment

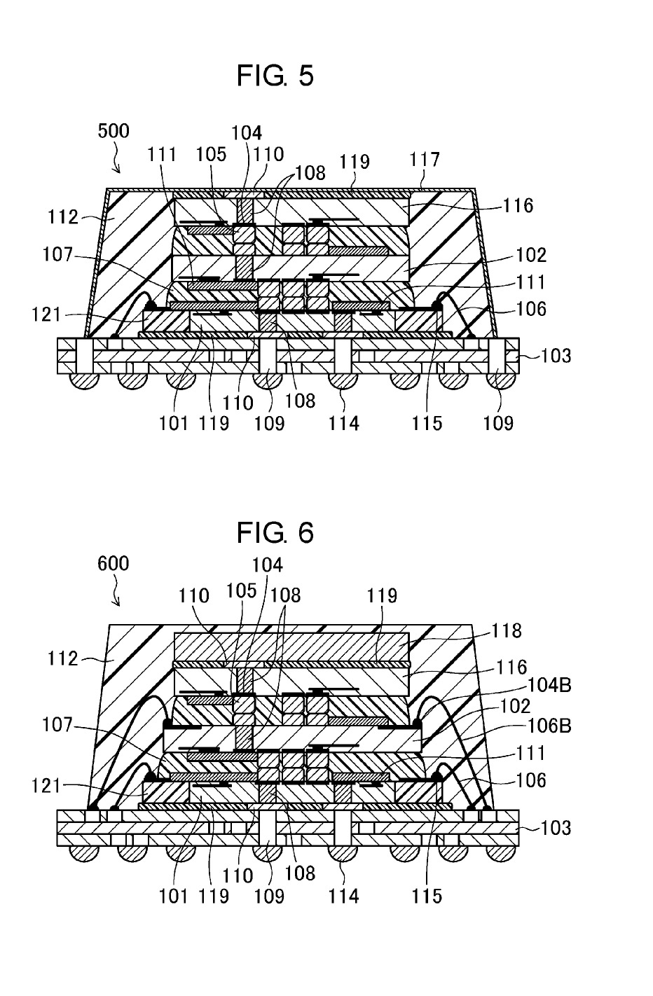

FIG. 5 is a cross-sectional view of semiconductor device 500 according to this variation. As shown in FIG. 5, according to semiconductor device 500, bumps 105 are disposed in different positions between the upper surface and the lower surface of second semiconductor chip 102 when planarly viewed. In addition, TSV electrode 108 formed in second semiconductor chip 102 is disposed at a position matching a position of bump 105 on the upper surface, but not at the position matching the position of bump 105 on the lower surface when planarly viewed. In addition, TSV electrode 108 formed in second semiconductor chip 102 is electrically connected to bump 105 on the lower surface through redistribution layer 111.

Furthermore, heat releasing plate 117 made of metal is provided so as to cover the chip stacked structure. Heat releasing plate 117 is electrically connected to substrate electrode 109 of substrate 103. In addition, TSV electrode 108 is formed in third semiconductor chip 116, and TSV electrode 108 is electrically connected to heat releasing plate 117 on the upper surface of third semiconductor chip 116 through a conductive resin or conductive film 110.

With this configuration, as for the power supply path between second semiconductor chip 102, and the first and third semiconductor chips 101 and 116 provided on its upper and lower sides, due to the formation of redistribution layer 111, its lateral position can be freely set without regard to the disposed position of bump 105. As a result, a degree of freedom in bonding the upper and lower chip layers can be improved in the chip stacked structure.

Redistribution layer 111 can be optionally formed on any of the upper surfaces and the lower surfaces of semiconductor chips 101, 102, and 116. Furthermore, the position of the power supply path can be changed optionally according to the position of redistribution layer 111. Furthermore, the wiring to configure the power supply path in the lateral direction of the chip may be the wiring in the chip other than redistribution layer 111. When the wiring in the chip is used in combination with redistribution layer 111, an effect of reducing the resistance of the power supply path can be more improved.

Furthermore, the conductive path can be ensured from an upper portion of uppermost third semiconductor chip 116 through substrate electrode 109, and the conductive resin or conductive film 110. Thus, in addition to the power supply voltage supplied from the lower portion of the conventional stacked chip structure, the power supply voltage can be supplied from the upper portion of the stacked chip structure, so that the voltage can be more effectively prevented from dropping due to the lack of the power supply voltage in third semiconductor chip 116.

In addition, heat releasing plate 117 is provided for one power supply system in FIG. 5, but when the plurality of strip-shaped heat releasing plates are disposed, they can be used for the plurality of power supply paths. In addition, TSV electrode 108 in third semiconductor chip 116 may be electrically connected to heat releasing plate 117 through a metal terminal such as solder or a bump, instead of the conductive resin or conductive film 110.

### Variation 5 of First Exemplary Embodiment

FIG. 6 is a cross-sectional view of semiconductor device 600 according to this variation. As shown in FIG. 6, according to semiconductor device 600, capacitor element (capacitance) 118 is provided so as to cover the upper portion of third semiconductor chip 116. TSV electrode 108 formed in third semiconductor chip 116 is electrically connected to capacitor element 118 through a conductive resin or conductive film 110. That is, TSV electrode 108 formed in first semiconductor chip 101, and TSV electrode 108 formed in second semiconductor chip 102 are also electrically connected to capacitor element 118.

In addition, wire bonding pad 104B is formed on second semiconductor chip 102, and wire 106B electrically connects wire bonding pad 104B to substrate 103 by wire bonding. In addition, a wire bonding pad may be provided on third semiconductor chip 116 and connected to the substrate 103 by wire bonding.

When the power supply or the ground wiring is connected to capacitor element 118, the power supply and the grounding can be prevented from fluctuating due to circuit operations of semiconductor chips 101, 102, and 116. As a result, the power supply voltage can be stably supplied to the center portion of the chip, so that the power supply voltage can be prevented from dropping in the center portion of the chip in the CoC structure. Furthermore, when the plurality of wire bonding structures are formed, the power supply can be reinforced in a middle layer of the chip stacked structure. Therefore, the power supply voltage can be stably supplied to the chip center portion, and the power supply voltage can be prevented from dropping in the chip center portion at the time of CoC bonding.

Furthermore, capacitor element 118 is disposed on the uppermost portion of the chip stacked structure in FIG. 6, but it may be disposed on another position. For example, it may be disposed on any one or each of the upper surfaces and the lower surfaces of semiconductor chips 101, 102, and 116. In addition, the capacitor element may be constituted by a semiconductor chip. In this case, even when a chip size of this capacitor element is smaller than the other semiconductor chips, the chip stacked structure can be stably formed by adding an expansion portion around an outer periphery of the chip body. Even when the capacitor element is not constituted by the semiconductor chip, the stacked structure can be formed by connecting it to the electrodes formed on the upper and lower surfaces of semiconductor chips 101, 102, and 116 through TSV electrodes 108.

### Another Exemplary Embodiment

The above exemplary embodiment and the variations show the configuration in which the two or three semiconductor chips are stacked, but the same effect can be provided in a configuration in which four or more semiconductor chips are stacked. In addition, the circuit formation surface of each semiconductor chip may be the upper surface or the lower surface. Furthermore, the TSV electrode may penetrate from the upper surface to the lower surface of the semiconductor chip, or it may penetrate from the in-chip wiring in the chip to a rear surface of the chip.

Furthermore, each semiconductor chip may have a circuit function other than the memory and the system LSI.

Furthermore, the above exemplary embodiment and variations have described the configuration in which the TSV electrode is formed in the lower chip connected to the substrate, and the power supply voltage is supplied (or grounded) from this TSV electrode to the lower chip and the upper chip, but as another configuration, the wire bonding and the TSV electrode may be formed in the upper chip instead of the lower chip to supply the power supply voltage. More specifically, the power supply voltage is supplied from the substrate to the upper chip through the wire bonding, and then the power supply voltage is supplied to the center portion of the lower chip through the TSV electrode formed in the upper chip. At this time, the wire bonding between the upper chip and the substrate for supplying the power supply voltage is to be provided with a wire thicker than the other signal lines. In addition, the power supply voltage can be stably supplied from the upper chip by use of the redistribution layer formed on the circuit surface of the lower chip.

In the above, the present disclosure has been described in detail based on the exemplary embodiment and its variations, but the present disclosure is not limited to the above exemplary embodiment and the like. Various variations and modifications can be made without departing from the scope of the present disclosure, and the present disclosure includes a case where a plurality of exemplary embodiments are combined, or the components are partially replaced with an alternative one which is not described in the exemplary embodiment.

According to the present disclosure, the power supply can be stably supplied to the center portions of the upper and lower chips at the time of CoC mounting, so that the present disclosure can be applied to various electronic devices using the semiconductor device having the CoC structure.

What is claimed is:

1. A semiconductor device comprising:
a substrate;
a first semiconductor chip placed on the substrate, having a circuit formation surface on an upper surface provided opposite to a surface facing the substrate, and including a through silicon via (TSV) electrode and a connection pad both electrically connected to the substrate;
a second semiconductor chip placed on the upper surface of the first semiconductor chip, and electrically connected to the first semiconductor chip through a bump;
a connection member for electrically connecting the connection pad of the first semiconductor chip to the substrate; and
a redistribution layer formed on the upper surface of the first semiconductor chip, and electrically connected to the TSV electrode,
wherein the connection pad formed on the upper surface of the first semiconductor chip is a wire bonding pad, and the connection member is a wire.

2. The semiconductor device according to claim 1, wherein
the first semiconductor chip has an expansion portion formed outwardly from side surfaces of a main body of the first semiconductor in a plan view, and
the connection pad is formed on the expansion portion.

3. The semiconductor device according to claim 1, wherein
the second semiconductor chip has at least one TSV electrode, and
the semiconductor device further comprises a third semiconductor chip placed on an upper surface of the second semiconductor chip, and electrically connected to the second semiconductor chip through at least one bump.

4. The semiconductor device according to claim 3, wherein
the second semiconductor chip has an expansion portion formed outwardly from side surfaces of a main body of the second semiconductor chip in a plan view.

5. The semiconductor device according to claim 1, wherein
a power supply wiring or a ground wiring is connected to the redistribution layer.

6. The semiconductor device according to claim 1, wherein
the TSV electrode formed in the first semiconductor chip is disposed at a position matching a position of the bump formed on the upper surface in a plan view, and is electrically connected to the bump.

7. The semiconductor device according to claim 1, wherein
the TSV electrode formed in the first semiconductor chip is disposed at a position not matching a position of the bump formed on the upper surface in a plan view, and is not electrically connected to the bump.

8. The semiconductor device according to claim 1, wherein
the TSV electrode formed in the first semiconductor chip is electrically connected to a substrate electrode of the substrate with a conductive resin or a conductive film.

9. The semiconductor device according to claim 1, wherein
the TSV electrode formed in the first semiconductor chip is electrically connected to a substrate electrode of the substrate with solder, a bump, or a redistribution layer.

10. The semiconductor device according to claim 3, wherein
the upper surface or a lower surface of the second semiconductor chip serves as a circuit formation surface.

11. The semiconductor device according to claim 3, wherein
the upper surface or a lower surface of the second semiconductor chip has a redistribution layer electrically connected to the TSV electrode formed in the second semiconductor chip.

12. The semiconductor device according to claim 3, further comprising a capacitor element stacked on the first to third semiconductor chips, wherein
the TSV electrode formed in the second semiconductor chip is electrically connected to the capacitor element.

13. The semiconductor device according to claim 3, wherein
disposed positions of the bumps are different between on the upper surface and on a lower surface of the second semiconductor chip in a plan view.

14. The semiconductor device according to claim 1, wherein
the substrate has a substrate electrode provided in a center portion, and a ball terminal provided on a surface opposite to a surface facing the first semiconductor chip and electrically connected to the substrate electrode, and
the TSV electrode in the first semiconductor chip is connected to the substrate electrode through a conductive member.

15. The semiconductor device according to claim 3, wherein
the second or the third semiconductor chip has a connection pad, and
the connection pad of the second or third semiconductor chip is electrically connected to the substrate by wire bonding.

16. The semiconductor device according to claim 1, wherein
a chip stacked structure having n (n is an integer greater than or equal to three) stacked semiconductor chips including the first and second semiconductor chips is formed on the substrate.

17. The semiconductor device according to claim 16, wherein
one of the n semiconductor chips has an expansion portion formed around a main body of the one of the n semiconductor chips in a plan view.

18. The semiconductor device according to claim 1, wherein
the TSV electrode formed in the first semiconductor chip is electrically connected to a wiring in the first semiconductor chip.

19. The semiconductor device according to claim 1, wherein
the TSV electrode formed in the first semiconductor chip is not electrically connected to a wiring in the first semiconductor chip.

20. The semiconductor device according to claim 1, wherein
a chip stacked structure including the first and second semiconductor chips, and an n-th (n is an integer greater than or equal to three) semiconductor chip stacked as an uppermost chip and having at least one TSV electrode is formed on the substrate,
the semiconductor device comprises a heat releasing plate provided so as to cover the chip stacked structure, and electrically connected to a substrate electrode of the substrate, and
the TSV electrode formed in the n-th semiconductor chip is electrically connected to the heat releasing plate.

21. The semiconductor device according to claim 1, wherein
each of the first and second semiconductor chips is a memory chip, or a system chip.
